(19) United States
(12) Patent Application Publication
(10) Pub. No.: US 2013/0156147 A1
(43) Pub. Date: Jun. 20, 2013

(54) HIGH SPEED COUNTER APPARATUS

(71) Applicant: Electronics and Telecommunications Research Institute, Daejeon (KR)

(72) Inventor: Kunal Jayant Dadia, Daejeon (KR)

(73) Assignee: Electronics and Telecommunications Research Institute, Daejeon (KR)

(21) Appl. No.: 13/716,006

(22) Filed: Dec. 14, 2012

(30) Foreign Application Priority Data
Dec. 15, 2011 (KR) 10-2011-0135942

(51) Int. Cl. H03K 21/02

(52) U.S. Cl. CPC H03K 21/026
USPC 377/55

(57) ABSTRACT

Disclosed is a high speed counter apparatus. The high speed counter apparatus includes a first counter configured to perform a count on the lower bits of the final output signal in response to a first clock signal, a second counter configured to perform a count on the upper bits of the final output signal in response to a second clock signal, and a clock signal generator configured to generate the second clock signal from the first clock signal. In accordance with the present invention, power consumption and a bottleneck phenomenon in an upper bit counter can be reduced because a second clock signal for operating the upper bit counter is synchronized with a first clock signal for operating the lower bit counter at a frequency lower than that of the clock signal for operating the lower bit counter.

### CROSS-REFERENCES TO RELATED APPLICATIONS

The present application claims priority under 35 U.S.C 119(a) to Korean Application No. 10-2011-0135942, filed on Dec. 15, 2011, in the Korean Intellectual Property Office, which is incorporated herein by reference in its entirety set forth in full.

### BACKGROUND

Exemplary embodiments of the present invention relate to a high speed counter apparatus, and more particularly, to a high speed counter apparatus in which two counters for counting the upper bits and lower bits of the final output signal are operated in response to clock signals having different frequencies.

In general, a frequency synthesizer, an Analog-to-Digital Converter (ADC), and a clock generator for providing a clock necessary for a microprocessor used in a wireless communication system is chiefly operated based on a Phase-Locked Loop (PLL).

This PLL has been commonly embodied using analog circuits, such as a Voltage Controlled Oscillator (VCO), a charge pump, and a loop filter, but the analog circuits are sensitive to a change of a process, voltage, and temperature. For this reason, researches are being carried out on an All-Digital Phase Locked Loop (ADPLL) using digital circuits.

FIG. 1 is a diagram showing a general structure of an ADPLL, and FIG. 2 is a diagram showing a common structure of a VPA.

As shown in FIG. 1, the ADPLL includes a Digitally-Controlled Oscillator (DCO), a Variable Phase Accumulator (VPA), and a Time-to-Digital Converter (TDC).

In this ADPLL, the frequency of an output signal of the DCO is determined by a signal inputted to the DCO, and information about the phase of the output signal is digitalized by the VPA and then provided to a control circuit.

In this case, phase errors may be alleviated by controlling the signal inputted to the DCO. If the ADPLL is constructed using the digital circuits as described above, the area of a chip may be reduced and there may be an advantage in terms of broadband frequency modulation.

In the ADPLL, the VPA is placed at the output terminal of the DCO using a signal having the highest frequency. Accordingly, a maximum output frequency of the DCO and a maximum frequency that may be generated from the ADPLL depend on a maximum frequency that may be supported by the VPA.

Accordingly, in the ADPLL, a design for the VPA capable of processing a high frequency signal is a very important issue.

As shown in FIG. 2, the VPA can be realized as the modulo incrernenter followed by a sampling register. Here, the sampling register is driven in response to the clock signal CKR having a relatively lower frequency than a clock signal CKV provided to the modulo incrementer. Therefore, the VPA has an output signal depending on a clock signal CKR having a low frequency.

Accordingly, the VPA shown in FIG. 2 has a simple structure, but is problematic in that a maximum output frequency of the DCO is limited because the VPA is operated at a low speed.

### SUMMARY

An embodiment of the present invention relates to a high speed counter apparatus which may be operated at a high frequency by using two counters for counting the upper bits and lower bits of the final output signal.

In one embodiment, a high speed counter apparatus includes a first counter configured to perform a count on the lower bits of the final output signal in response to a first clock signal, a second counter configured to perform a count on the upper bits of the final output signal in response to a second clock signal, and a clock signal generator configured to generate the second clock signal from the first clock signal.

In the present invention, the second clock signal may be synchronized with the first clock signal at a frequency lower than a frequency of the first clock signal.

In the present invention, the lower bits may be 2 bits.

In the present invention, the second clock signal may be synchronized with the first clock signal at a frequency that is a quarter of the frequency of the first clock signal.

In the present invention, the first counter may operate as a toggle incrementer.

In the present invention, the first counter may include one or more D flip-flops configured in a toggle manner.

In the present invention, the second counter may operate as a modulo incrementer.

In the present invention, the second counter includes one or more adders, corresponding to the number of the upper bits, and a flip-flop.

In the present invention, the clock signal generator may include one or more logic gate circuits and flip-flops and generate the second clock signal so that the second clock signal is triggered in response to a change in a specific state of a signal outputted from the first counter.

In the present invention, the clock signal generator may include one or more D flip-flops configured in a toggle manner.

In the present invention, the clock signal generator may delay a most significant bit of a signal outputted from the first counter and generate the second clock signal so that the second clock signal is triggered in response to a change in the state of the delayed most significant bit.

### BRIEF DESCRIPTION OF THE DRAWINGS

The above and other aspects, features and other advantages will be more clearly understood from the following detailed description taken in conjunction with the accompanying drawings, in which:

FIG. 1 is a diagram showing a general structure of an ADPLL;

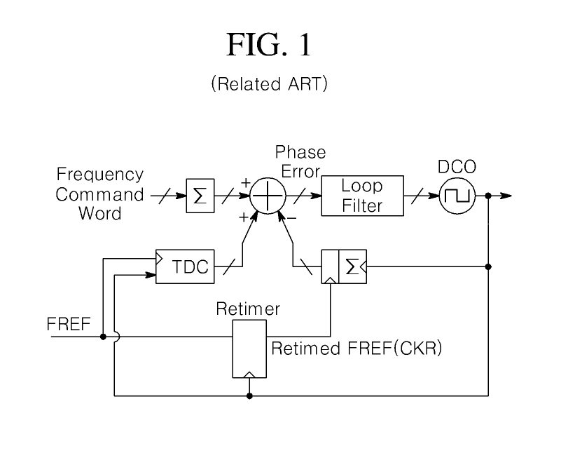

FIG. 2 is a diagram showing a common structure of a VPA;

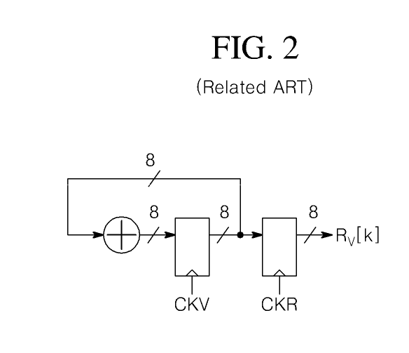

FIG. 3 is a circuit diagram of a high speed counter apparatus according to an embodiment of the present invention;

FIG. 4 is a diagram showing an example of a clock signal generator in the high speed counter apparatus according to the embodiment of the present invention;

FIG. 5 is a diagram showing another example of the clock signal generator in the high speed counter apparatus according to the embodiment of the present invention; and

FIG. 6 is a graph showing the results of a simulation of the high speed counter apparatus according to the embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

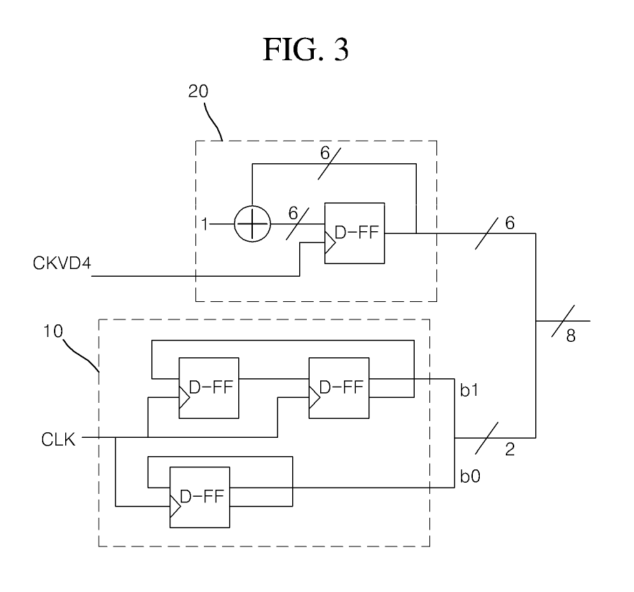

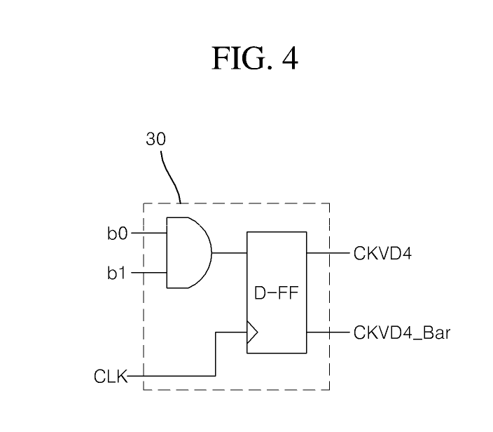

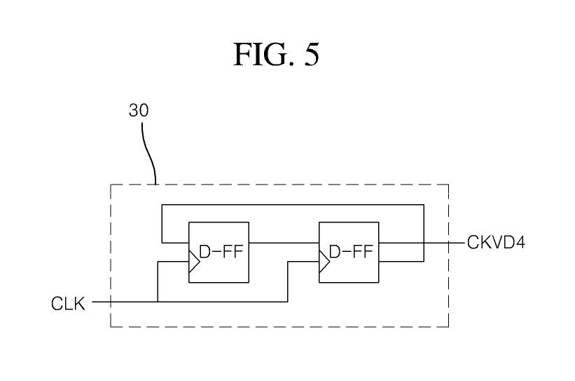

FIG. 3 is a circuit diagram of a high speed counter apparatus according to an embodiment of the present invention, FIG. 4 is a diagram showing an example of a clock signal generator in the high speed counter apparatus according to the embodiment of the present invention, and FIG. 5 is a diagram showing another example of the clock signal generator in the high speed counter apparatus according to the embodiment of the present invention.

As shown in FIGS. 3 to 5, the high speed counter apparatus according to the embodiment of the present invention includes a first counter 10, a second counter 20, and a clock signal generator 30.

The first counter 10 performs a count operation on the lower bits of the final output signal in response to a first clock signal CLK.

The first counter 10 includes one or more flip-flops configured in a toggle manner and may operate as a 2-bit toggle incrementer.

The toggle manner refers to a manner of feeding back the inverse output of a D flip-flop as the input to the D flip-flop, as shown in FIG. 3.

As shown in FIG. 3, the first counter 10 may include, for example, three D flip-flops D-FFs configured in the toggle manner. Single toggle D flip-flop on the lower side may output a bit ‘b₀’, and two D flip-flops on the upper side are cascaded in the toggle manner and configured to output a bit ‘b₁’.

Therefore, the bit ‘b₀’ may be changed like ‘0’->‘1’ or ‘1’->‘0’ at each rising edge of the first clock signal CLK, and the bit ‘b₁’ may be sequentially changed at each alternate rising edge of the two flip-flops.

Accordingly, the output signal of the 2 bits ‘b₁’ and ‘b₀’ outputted from the first counter 10 may be changed like ‘00’->‘01’->‘10’->‘11’->‘00’ at all the rising edges of the first clock signal CLK.

The second counter 20 performs a count operation on the upper bits of the final output signal in response to a second clock signal CKVD4.

The second counter 20 includes one or more adders, corresponding to the number of upper bits, and a flip-flop D-FF, and may operate as a 6-bit modulo incrernenter. The second counter 20 reduces glitch by maintaining synchronization between upper bits.

In the second counter 20, one input to an adder of a bit ‘b2’ is a binary number ‘1’, and the other input is fed back from the output of a flip-flop following the adder.

The adder of a bit ‘b2’ is a half-adder, and adders of the remaining bits ‘b3’, . . . , ‘b7’ are full-adders. A carry input to each of the full-adders is generated from the carry input of a previous adder.

Therefore, an increase of a bit is repeated at each rising edge of the second clock signal CKVD4, and the bits ‘b7’, . . . , ‘b2’ increase from ‘000000’ to ‘111111’. Next, when the bits reach a maximum value ‘111111’, the second counter 20 returns to ‘000000’ and then continues to perform a count operation.

The second counter 20 may be embodied so that it performs a count operation in response to the second clock signal CKVD4 having a lower frequency than the first clock signal CLK.

More particularly, the second counter 20 may be embodied so that it increases a count by ‘1’ at each fourth rising edge of the first clock signal CLK.

For example, the second counter 20 may increase a count by ‘1’ at a point of time at which the bits ‘b₁’ and ‘b₀’ outputted from the first counter 10 are changed from ‘11’ to ‘00’ at the rising edge of the first clock signal CLK.

To this end, the second clock signal CKVD4 provided to the second counter 20 must have a frequency that is a quarter of the frequency of the first clock signal CLK provided to the first counter 10. A detailed method of generating the second clock signal CKVD4 having this frequency will be described later.

The clock signal generator 30 generates the second clock signal CKVD4 from the first clock signal CLK and provides the second clock signal CKVD4 to the second counter 20.

Here, the second clock signal CKVD4 may be generated from various sources, but it is preferred that the second clock signal

CKVD4 be synchronized with the first clock signal CLK for a continuous count operation without glitch.

The clock signal generator 30 may generate the second clock signal CKVD4 in response to a change in a specific state of a signal outputted from the first counter 10 by using one or more logic gate circuits and flip-flops.

In detail, the clock signal generator 30 may generate the second clock signal CKVD4 in response to a change in a specific state of the bits ‘b₁’ and ‘b₀’ by using, for example, an AND gate circuit and a D flip-flop D-FF as shown in FIG. 4.

That is, the clock signal generator 30 may be embodied so that the AND gate circuit transfers high logic to the D flip-flop when the bits ‘b₁’ and ‘b₀’ outputted from the first counter 10 are ‘11’ and thus the second clock signal CKVD4 is triggered to high logic at the next rising edge of the first clock signal CLK.

The second counter 20 increases a count by ‘1’ at the rising edge of the second clock signal CKVD4 and, at the same time, the bits ‘b₁’ and ‘b₀’ of the first counter 10 are toggled from ‘11’ to ‘00’. That is, the second clock signal CKVD4 is triggered whenever the bits ‘b₁’ and ‘b₀’ are changed from ‘11’ to ‘00’.

Therefore, the clock signal generator 30 may generate the second clock signal CKVD4 synchronized with the first clock signal CLK at a frequency that is a quarter of the frequency of the first clock signal CLK.

Meanwhile, the clock signal generator 30 may generate the second clock signal CKVD4 by using the one or more D flip-flops configured in the toggle manner.

As shown in FIG. 5, the clock signal generator 30 may generate the second clock signal CKVD4 by using, for example, two

D flip-flops cascaded in the toggle manner.

In this case, the output signal of the cascaded D flip-flops has a frequency that is a quarter of the frequency of the first clock signal CLK. Accordingly, the cascaded D flip-flops may generate the second clock signal CKVD4 synchronized with the first clock signal CLK at a frequency that is a quarter of the frequency of the first clock signal CLK.

There is one flip-flop delay between the first clock signal CLK and the second clock signal CKVD4 because the first clock signal CLK is a basic clock necessary to generate the second clock signal CKVD4, but the flip-flop delay may be easily offset.

The clock signal generator 30 may generate the second clock signal CKVD4 using various methods in addition to the above method.

For example, the clock signal generator 30 may generate the second clock signal CKVD4 synchronized with the first clock signal CLK at a frequency that is a quarter of the frequency of the first clock signal CLK by delaying the bit ‘b₁’, that is, the most significant bit, of a signal outputted from the first counter 10 by two clocks of the first clock signal CLK.

As described above, the high speed counter apparatus according to the present invention may be embodied as an 8-bit phase accumulator operated in response to the first clock signal CLK.

The final output signal of 8 bits are combined an output signal of lower 2 bits outputted from the first counter 10 with an output signal of upper 6 bits outputted from the second counter 20.

In this case, the first counter 10 performs fine count control for a count from ‘00’ to ‘11’ like a modulo-4 counter, and the second counter 20 performs coarse count control for a count from ‘000000’ to ‘111111’ by a multiple of 4. A continuous count from 0 to 255 may be obtained when the first counter 10 and the second counter 20 are combined.

If the second clock signal CKVD4 is synchronized with the first clock signal CLK at a frequency lower than that of the first clock signal CLK as described above, disadvantages, such as a low speed and glitch which may be generated in the second counter 20, can be improved. Furthermore, power consumption can be reduced because the number of logic circuits is reduced.

In addition, a VPA capable of operating at a high frequency can be realized because the first counter 10 can be operated at high speed.

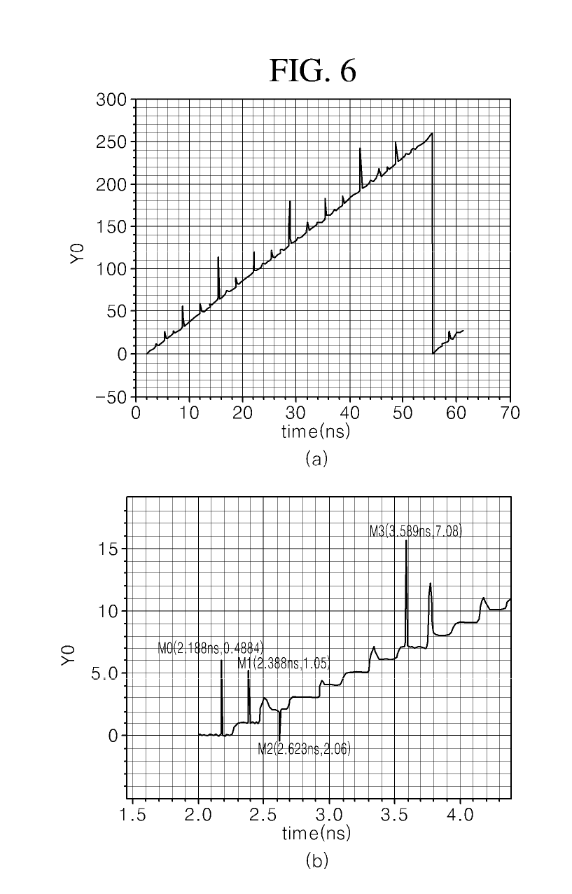

FIG. 6 is a graph showing the results of a simulation of the high speed counter apparatus according to the embodiment of the present invention. The graph shows the results when the high speed counter apparatus is operated at a frequency of 4.8 GHz. FIG. 6(a) shows the steps in detail with glitches and FIG. 6(b) shows the operation in general for the entire count cycle 0->255->0.

From FIG. 6, it may be checked that the high speed counter apparatus according to the present invention is normally operated at a high frequency of 4.8 GHz.

Meanwhile, the high speed counter apparatus according to the present embodiment may be applied to a VPA applied to an ADPLL, but not limited thereto. For example, the high speed counter apparatus according to the present embodiment may be applied to various devices requiring a count operation.

Furthermore, in the high speed counter apparatus according to the present embodiment, the first counter 10 is illustrated as being the 2-bit toggle incrementer and the second counter 20 is illustrated as being the 6-bit modulo incrementer. However, the first counter 10 and the second counter 20 may be configured so that they are operated at various numbers of bits in response to the final output signal of various bits.

In accordance with the present invention, power consumed by the upper bit counter can be reduced and a bottleneck phenomenon which may be occurred in the upper bit counter can be obviated because a clock signal for operating the upper bit counter is synchronized with a clock signal for operating the lower bit counter at a frequency lower than that of the clock signal for operating the lower bit counter.

In accordance with the present invention, an ADPLL capable of generating a signal having a high frequency can be embodied because the lower bit counter operated in response to the output signal of a DCO can be operated at high speed.

Furthermore, in accordance with the present invention, the area of a chip can be reduced because a clock signal for operating the upper bit counter can be generated by using the toggle incrementer without using an additional combination logic circuit including an encoder and an adder.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A high speed counter apparatus, comprising:
a first counter configured to perform a count on lower bits of a final output signal in response to a first clock signal;
a second counter configured to perform a count on upper bits of the final output signal in response to a second clock signal; and
a clock signal generator configured to generate the second clock signal from the first clock signal.

2. The high speed counter apparatus of claim 1, wherein the second clock signal is synchronized with the first clock signal at a frequency lower than a frequency of the first clock signal.

3. The high speed counter apparatus of claim 1, wherein the lower bits are 2 bits.

4. The high speed counter apparatus of claim 3, wherein the second clock signal is synchronized with the first clock signal at a frequency that is a quarter of a frequency of the first clock signal.

5. The high speed counter apparatus of claim 1, wherein the first counter operates as a toggle incrementer.

6. The high speed counter apparatus of claim 5, wherein the first counter comprises one or more D flip-flops configured in a toggle manner.

7. The high speed counter apparatus of claim 1, wherein the second counter operates as a modulo incrementer.

8. The high speed counter apparatus of claim 7, wherein the second counter comprises one or more adders, corresponding to a number of the upper bits, and a flip-flop.

9. The high speed counter apparatus of claim 1, wherein the clock signal generator comprises one or more logic gate circuits and flip-flops and generates the second clock signal so that the second clock signal is triggered in response to a change in a specific state of a signal outputted from the first counter.

10. The high speed counter apparatus of claim 1, wherein the clock signal generator comprises one or more D flip-flops configured in a toggle manner.

11. The high speed counter apparatus of claim 1, wherein the clock signal generator delays a most significant bit of a signal outputted from the first counter and generates the second clock signal so that the second clock signal is triggered in response to a change in a state of the delayed most significant bit.
